(19) United States
(12) Patent Application Publication
(10) Pub. No.: US 2019/0136366 A1
(43) Pub. Date: May 9, 2019

(54) CRUCIBLE AND VAPOR DEPOSITION METHOD

(71) Applicant: SHENZHEN CHINA STAR OPTOELECTRONICS SEMICONDUCTOR DISPLAY TECHNOLOGY CO., LTD., Shenzhen (CN)

(72) Inventors: Xiaoping QIAO, Shenzhen (CN); Jinchuan LI, Shenzhen (CN)

(21) Appl. No.: 16/057,944

(22) Filed: Aug. 8, 2018

Related U.S. Application Data
(63) Continuation of application No. PCT/CN2018/072620, filed on Jan. 15, 2018.

(30) Foreign Application Priority Data
Nov. 8, 2017 (CN) 201711093595.X

(51) Int. Cl. C23C 14/24; H01L 51/00; H01L 51/56

(52) U.S. Cl. CPC C23C 14/243; H01L 51/56; H01L 51/001

(57) ABSTRACT

The present application provides a crucible includes a first crucible and a second crucible disposed in the first crucible, wherein a cavity structure is formed between the first crucible and the second crucible so that a cross-section of the cavity is an annular shape; the cavity is configured to accommodate a vapor deposition material, a first heating component is arranged surround an outer wall surface of the first crucible facing away from the second crucible, a second heating component is arranged around the inner wall surface of the second crucible facing away from the first crucible, the crucible further includes a heating control system that controls different heating durations of the first heating component and the second heating component. With the above arrangement, the crucible of the present application is free from the problem of deformation or cracking. The present application also provides a crucible vapor deposition method.

### RELATED APPLICATIONS

This application is a continuation application of PCT Patent Application No. PCT/CN2018/072620, filed Jan. 15, 2018, and claims the priority of China Application CN 201711093595.X, filed Nov. 8, 2017, which is herein incorporated by reference in its entirety.

### FIELD OF THE DISCLOSURE

The present application relates to the field of vapor deposition technology, and in particular relates to a crucible and a vapor deposition method.

### BACKGROUND OF THE DISCLOSURE

OLED is self-luminous, thin, easy to achieve flexible display and so on, is a new generation of display technology with good development prospects. At present, in the OLED panel manufacturing process, the vapor deposition of the OLED material generally adopts the physical vapor deposition method, that is, the organic material is heated in a crucible placed in a vacuum chamber to sublimate or vaporize the organic material to form a film on the substrate. Some metal materials need to be heated to a relatively high temperature (500° C. or even above 1000° C.) in order to liquefy or vaporize. For metal vapor deposition, high temperature crucibles are needed.

General high-temperature metal crucibles are cylindrical, the metal material is heated and then liquefied, the vaporized metal atoms are ejected from the crucible port, after the heating is stopped, the metal material in the metal crucible contracts, causing a certain pulling force to the crucible side wall, resulting in deformation or even breakage of the crucible.

### SUMMARY OF THE DISCLOSURE

The purpose of the present application is to provide a crucible to solve the problem of deformation and damage of the crucible existing in the prior art.

For the purpose of the present application, the present application provides the following technical solutions.

According to a first aspect, a crucible includes a first crucible and a second crucible disposed in the first crucible, wherein a cavity structure is formed between the first crucible and the second crucible so that a cross-section of the cavity is an annular shape; the cavity is configured to accommodate a vapor deposition material, a first heating component is arranged surround an outer wall surface of the first crucible facing away from the second crucible, a second heating component is arranged around the inner wall surface of the second crucible facing away from the first crucible, the crucible further includes a heating control system that controls different heating durations of the first heating component and the second heating component.

In a first possible implementation manner of the first aspect, the first heating component is disposed close to the outer wall surface of the first crucible, and the second heating component is disposed close to the inner wall surface of the second crucible.

With reference to the first aspect and the first possible implementation manner of the first aspect, in a second possible implementation manner of the first aspect, the heating temperature provided by the first heating component and the second heating component ranges from 400° C. to 1500° C.

In a third possible implementation manner of the first aspect, the crucible further includes a cover, the cover covers the end of the top of the cavity, the cover has an opening.

With reference to the first aspect and the third possible implementation manner of the first aspect, in a fourth possible implementation manner of the first aspect, the cover has a plurality of openings arranged around the annular shape of the first crucible.

In a fifth possible implementation manner of the first aspect, the first crucible and the second crucible are round shape, and the diameter of the second crucible is 30%-60% of the diameter of the first crucible.

In a sixth possible implementation manner of the first aspect, the cavity is provided with a temperature sensor.

The present application also provides a vapor deposition method using the following technical solutions.

In a second aspect, a crucible vapor deposition method includes the following steps:

providing a crucible, including a first crucible and a second crucible disposed in the first crucible, forming a cavity structure between the first crucible and the second crucible, embedding a vapor deposition material in the cavity;
disposing a first heating component surround an outer wall surface of the first crucible facing away from the second crucible and disposing a second heating component surround an inner wall surface of the second crucible facing away from the first crucible;
turning on the first heating component and the second heating component simultaneous by a heating control system to increase a temperature for sublimating, melting or evaporating the vapor deposition material;
turning off the second heating component after the vapor deposition is completed, maintaining the first heating component in a heated state and then turning off the first heating component when the vapor deposition material is separated from the first crucible.

In a first possible implementation of the second aspect, the heating temperature of the first heating component and the second heating component is controlled to be in the range of 400° C. to 1500° C.

In a second possible implementation of the second aspect, the heating temperature of the first heating component and the second heating component is controlled to be in the range of 500° C. to 1200° C.

Beneficial effects of the present application:

a crucible provided by the present application is provided with an annular cavity, a first heating component is arranged on the outer wall of the crucible, a second heating component is arranged on the inner wall of the crucible, controlling the heating durations of the first heating component and the second heating component by the heating control system is different so that the crucible of the present application will not be deformed or cracked.

### BRIEF DESCRIPTION OF THE DRAWINGS

To describe the technical solutions in the embodiments of the present application or in the prior art more clearly, the following briefly introduces the accompanying drawings required for describing the embodiments or the prior art. Apparently, the accompanying drawings in the following description show merely some embodiments of the application, and a person of ordinary skill in the art may still derive other drawings from these accompanying drawings without creative efforts.

FIG. 1 is a schematic diagram of the crucible in the prior art.

FIG. 2 is a schematic diagram of the crucible used in FIG. 1.

FIG. 3 is a schematic diagram of the crucible three-dimensional structure of an embodiment of the present disclosure.

FIG. 4 is a schematic cross-sectional view of the crucible in the radial direction in FIG. 3.

FIG. 5 is a schematic diagram of the use of the crucible in FIG. 4.

### DETAILED DESCRIPTION OF PREFERRED EMBODIMENTS

The technical solutions in the embodiments of the present application are clearly and completely described below with reference to the accompanying drawings in the embodiments of the present application. Apparently, the described embodiments are merely some but not all of the embodiments of the present application. All other embodiments obtained by a person of ordinary skill in the art based on the embodiments of the present application without creative efforts shall fall in the protection scope of this application.

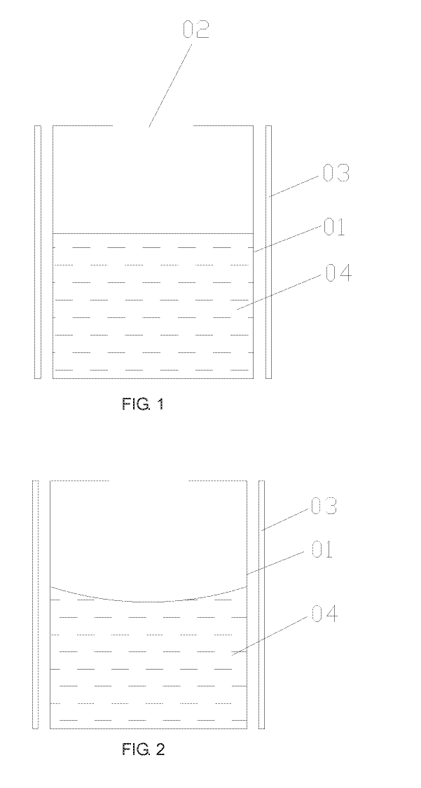

Please refer to FIG. 1, which is a structural diagram of the crucible in the prior art including a crucible 01 and a heating portion 03, the top of the crucible having an opening 02, the crucible 01 having a barrel structure, including an inner cavity, and containing a metal vapor deposition material 04. The heating portion 03 is disposed around the outer wall of the crucible 01.

Please refer to FIG. 2, which is a structural diagram of the crucible used in the prior art. After the crucible is fully used, the metal vapor deposition material 04 in the crucible is gradually cooled and contracted after the heating portion 03 is closed. Due to thermal expansion and contraction, the metal vapor deposition material 04 will produce a tensile force on the side wall of the crucible 01, which may cause the crucible 01 to be deformed or even cracked, which will seriously affect the crucible vapor deposition process.

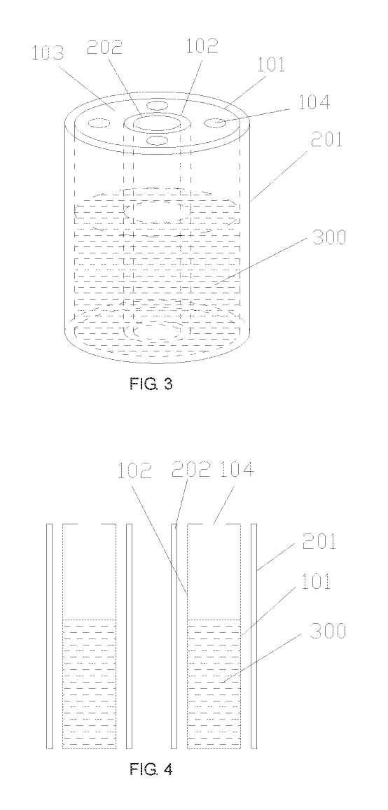

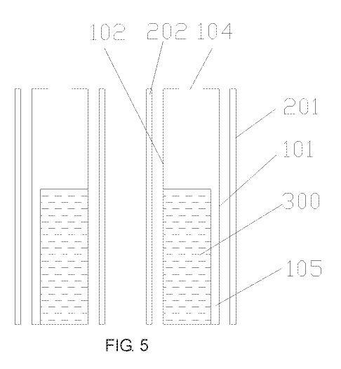

Please refer to FIG. 3 to FIG. 5, an embodiment of the present application provides a crucible including a first crucible 101 and a second crucible 102 disposed in the first crucible 101 opposite to the first crucible 101, the first crucible 101 and the second crucible 102 are enclosed to form a cavity structure such that the cavity is formed into a ring shape in a cross section, the cavity is configured to accommodate the vapor deposition material 300, a first heating component 201 is surrounded by the first crucible 101 facing away from the outer wall surface of the second crucible 102, a second heating component 202 is surrounded by the second crucible 102 facing away from the inner wall surface of the first crucible 101, the crucible further includes a heating control system (not shown). The heating control system controls the heating durations of the first heating component 201 and the second heating component 202 to be different.

In this embodiment, the annular cavity is provided, the first heating component 201 is arranged on the outer wall of the crucible, the second heating component 202 is arranged on the inner wall of the crucible, the different heating durations of the first heating component 201 and the second heating component 202 are controlled by the heating control system so that the crucible of the present application will not be deformed or cracked.

In the present embodiment, the working process of the heating control system is as follows: the vapor deposition starts, while the first heating component 201 and the second heating component 202 are activated; the heating state is maintained; after the vapor deposition is completed, the second heating component 202 is closed first, the first heating component 201 is kept in the heating state, and the material to be evaporated 300 is separated from the first crucible 101 and then turned off, so that the heating durations of the first heating component 201 and the second heating component 202 are different. In other embodiments, the second embodiment is substantially the same as the present embodiment, except that the first heating component 201 is closed and the second heating component 202 is closed.

Please refer to FIG. 5, after the above heating process, since the temperature of the side of the second heating component 202 that has been turned off is low due to the high temperature on the side of the first heating component 201 that is continuously heated, the vapor deposition material 300 is still in a state of high temperature melting near the first heating component 201 and has good fluidity so that the vapor deposition material 300 flows toward the second heating component 202 with a lower temperature. Finally, all of the vapor deposition material 300 shrinks to the side of the second crucible 102, on the side wall of the first crucible 101, there is no vapor deposition material 300, and the vapor deposition material 300 completely separates from the first crucible 101 to form the gap 105. At this time, the first heating component 101 is closed, since the vapor deposition material 300 is no longer connected between the first crucible 101 and the second crucible 102, no pulling force is generated on the first crucible 101, thereby solving the problem of deformation or breakage of the crucible.

In the present embodiment, the distance between the first heating component 201 and the outer wall surface of the first crucible 101 ranges from 1 to 100 mm and the distance between the second heating component 202 and the inner wall surface of the second crucible 102 ranges from 1 to 100 mm. Preferably, the distance between the first heating component 201 and the outer wall of the first crucible 101 ranges from 5 to 50 mm and the distance between the second heating component 202 and the inner wall of the second crucible 102 ranges from 5 to 50 mm.

In the present embodiment, the first crucible 101 and the second crucible 102 can be made of a refractory metal material, such as steel, or a refractory inorganic material, such as ceramic. It can be understood that a bottom plate (not labeled) is connected to the bottom end surface of the first crucible 101 and the second crucible 102, the bottom plate is arranged at the end of the cavity, and the cavity is formed by the first crucible 101, the second cavity 102 and the bottom board. The crucible further includes a cover 103 covering an end of the top of the cavity, the cover 103 having an opening 104. Further, there are a plurality of openings 104 in the cover 103 and arranged around the center of the first crucible 101 in a ring shape. The shape of the opening 104 may be circular or may be other shapes. The first crucible 101 and the second crucible 102 are circular, the diameter of the second crucible 102 is 30%-60% of the diameter of the first crucible 101. Preferably, the diameter of the second crucible 102 is 40%-50% of the diameter of the first crucible 101. Preferably, the diameter of the second crucible 102 is 40% or 50% of the diameter of the first crucible 101.

The vapor deposition material 300 is a metal material and is heated by a crucible of the present application to form steam for vapor deposition onto the substrate to form an OLED layer.

In an implementation manner, the first heating component 201 is disposed close to the outer wall surface of the first crucible 101, and the second heating component 202 is disposed close to the inner wall surface of the second crucible 102. The close contact between the first heating component 201 and the second heating component 202 makes the heating efficiency higher and the heat loss less, which is favorable for improving the thermal efficiency of the crucible and reducing the energy consumption.

In an implementation manner, the heating temperature provided by the first heating component 201 and the second heating component 202 ranges from 400° C. to 1500° C. Preferably, the heating temperature provided by the first heating component 201 and the second heating component 202 ranges from 500° C. to 1200° C. Further preferably, the heating temperature provided by the first heating component 201 and the second heating component 202 ranges from 800° C. to 1000° C., In the present embodiment, examples are provided in which the heating temperature provided by the first heating component 201 and the second heating component 202 is any one of 400° C., 500° C., 600° C., 700° C., 800° C., 900° C., 1000° C., 1100° C., 1200° C., 1300° C., 1400° C., and 1500° C. Further, a temperature sensor (not shown) is disposed in the cavity. Through the temperature control in the present embodiment, the crucible has a good temperature application range. By providing the temperature sensor, the temperature in the crucible can be monitored in real time, facilitating the staff to perform the vapor deposition process according to a better operation.

Referring to FIG. 3 to FIG. 5, an embodiment of the present application provides a crucible vapor deposition method, including the following steps:

providing a crucible, including a first crucible 101 and a second crucible 102 disposed in the first crucible 101 opposite to the first crucible 101, enclosing the first crucible 101 and the second crucible 102 to form a cavity structure, installing a vapor deposition material 300 in the cavity;
disposing a first heating component 201 surrounding the outer wall surface of the first crucible 101 facing away from the second crucible 102 and disposing a second heating component 202 surrounding the inner wall surface of the second crucible 102 facing away from the first crucible 101;
turning on the first heating component 201 and the second heating component 202 simultaneous by a heating control system to increase a temperature for sublimating, melting or evaporating the vapor deposition material 300;
turning off the second heating component 202 after the vapor deposition is completed, maintaining the first heating component 201 in a heated state and then turning off the first heating component 201 when the vapor deposition material 300 is separated from the first crucible 101.

Through the vapor deposition method of the embodiment, during the vapor deposition process of the crucible, the first crucible 101 and the second crucible 102 are not deformed or cracked, so as to ensure the progress of the vapor deposition process.

In this embodiment, the heating temperature of the first heating component 201 and the second heating component 202 is controlled to be in the range of 400° C. to 1500° C. Further, the heating temperature of the first heating component 201 and the second heating component 202 is controlled to be in the range of 500° C. to 1200° C. Further preferably, the heating temperature provided by the first heating component 201 and the second heating component 202 ranges from 800° C. to 1000° C. In addition, in the present embodiment, an example is provided in which the heating temperature provided by the first heating component 201 and the second heating component 202 is any one of 400° C., 500° C., 600° C., 700° C., 800° C., 900° C., 1000° C., 1100° C., 1200° C., 1300° C., 1400° C., and 1500° C.

The above disclosure is only one preferred implementation of the present application, and certainly can not be used to limit the scope of the present application. Those of ordinary skill in the art can understand that all or part of the processes for implementing the foregoing embodiments and equivalent changes made according to the claims of the present application still fall within the scope of the application.

What is claimed is:

1. A crucible, comprising a first crucible and a second crucible disposed in the first crucible, wherein a cavity structure is formed between the first crucible and the second crucible so that a cross-section of the cavity is an annular shape; the cavity is configured to accommodate a vapor deposition material, a first heating component is arranged surround an outer wall surface of the first crucible facing away from the second crucible, a second heating component is arranged around an inner wall surface of the second crucible facing away from the first crucible, the crucible further comprises a heating control system that controls different heating durations of the first heating component and the second heating component.

2. The crucible according to claim 1, wherein the first heating component is disposed close to the outer wall surface of the first crucible, and the second heating component is disposed close to the inner wall surface of the second crucible.

3. The crucible according to claim 1, wherein the heating temperature provided by the first heating component and the second heating component ranges from 400° C. to 1500° C.

4. The crucible according to claim 2, wherein the heating temperature provided by the first heating component and the second heating component ranges from 400° C. to 1500° C.

5. The crucible according to claim 1, wherein the crucible further comprises a cover, the cover covers an end of a top of the cavity, the cover has an opening.

6. The crucible according to claim 5, wherein the cover has a plurality of openings arranged around an annular shape of the first crucible.

7. The crucible according to claim 1, wherein the first crucible and the second crucible are round shape, and the diameter of the second crucible is 30%-60% of the diameter of the first crucible.

8. The crucible according to claim 1, wherein the cavity is provided with a temperature sensor.

9. A crucible vapor deposition method, comprising the steps of:
providing a crucible, comprising a first crucible and a second crucible disposed in the first crucible, forming a cavity structure between the first crucible and the second crucible, embedding a vapor deposition material in the cavity;
disposing a first heating component surround an outer wall surface of the first crucible facing away from the second crucible and disposing a second heating component surround an inner wall surface of the second crucible facing away from the first crucible;
turning on the first heating component and the second heating component simultaneous by a heating control system to increase a temperature for sublimating, melting or evaporating the vapor deposition material;
turning off the second heating component after the vapor deposition is completed, maintaining the first heating component in a heated state and then turning off the first heating component when the vapor deposition material is separated from the first crucible.

10. The crucible vapor deposition method according to claim 9, wherein the heating temperature of the first heating component and the second heating component is controlled to be in the range of 400° C. to 1500° C.

11. The crucible vapor deposition method according to claim 10, wherein the heating temperature of the first heating component and the second heating component is controlled to be in the range of 500° C. to 1200° C.
